(19) United States
(12) Patent Application Publication
(10) Pub. No.: US 2010/0181658 A1
(43) Pub. Date: Jul. 22, 2010

(54) Semiconductor device which exposes die pad without covered by interposer and its manufacturing method

(75) Inventor: Takanori Yamashita, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/654,928

(22) Filed: Jan. 8, 2010

(30) Foreign Application Priority Data
Jan. 19, 2009 (JP) 2009-009071

(51) Int. Cl. H01L 23/495; H01L 21/60; H01L 23/498

(52) U.S. Cl. 257/676; 438/123; 257/692; 257/E23.031; 257/E23.06; 257/E21.506; 257/E21.502

(57) ABSTRACT

A semiconductor device, includes a lead frame including a die pad of which back side surface is exposed to the back side of a package, as well as a plurality of land terminals, a resin filled between the die pad and each of the land terminals so as to enable the die pad and each of the land terminals to be fastened mutually, and a semiconductor chip having a plurality of pads and being mounted on a top side of the die pad. The semiconductor device further includes an interposer having a bonding stitch on its top side, being disposed on the top side surface of the lead frame, and relaying an electrical connection of at least any one of the plurality of pads to at least any one of the land terminals, and a first bonding wire bonded to the bonding stitch of the interposer and one of the plurality of pads of the semiconductor chip.

### INCORPORATION BY REFERENCE

This application is based upon and claims the benefit of priority from Japanese Patent Application No. 2009-009071 which was filed on Jan. 19, 2009, the disclosure of which is incorporated herein in its entirety by reference.

### BACKGROUND OF THE INVENTION

1. Field of the Invention

The present invention relates to a semiconductor device and its manufacturing method.

2. Description of Related Art

FIG. 7 illustrates part of a package structure of a semiconductor device disclosed in the patent document 1 (Japanese Patent Application Laid Open No. 2008-186869). FIG. 7A is a top view of a lead frame 100 included in the package structure. FIG. 7B is a cross sectional view taken on line X-X of FIG. 7A and FIG. 7C is a cross sectional view taken on line Y-Y of FIG. 7A.

As shown in FIG. 7, the lead frame 100 includes an external terminal 101, a chip connection terminal 102, a lead 103, a die pad 104, a frame part 105, tape 106, and a connecting part 107.

FIG. 8 illustrates a series of processes for describing how to manufacture the lead frame 100 shown in FIG. 7.

At first, a photo-resist film 132 is formed on each of the front and back side surfaces of a lead frame base 131 (FIG. 8A). Then, the photo-resist film 132 on each of those front and back side surfaces is processed into predetermined photo-resist patterns 134S and 134R (FIG. 8B).

After that, half-etching is carried out for the chip-mounted surface of the lead frame base 131 while a protective sheet 135 is stuck on the back side surface of the lead frame base 131, thereby forming recessed parts 136 in the chip-mounted surface (FIG. 8C).

After that, the photo-resist patterns 134S are removed and resin 137 is filled in those recessed parts 136 (FIG. 8D). Then, the protective sheet 135 is peeled off and half-etching is carried out for the back side surface of the lead frame base 131 to form recessed parts 138 (FIG. 8E).

Then, tape 139 is stuck on the back side surface of the lead frame base 131 (FIG. 8F). After that, the resin 137 is removed, thereby obtaining a lead frame 100 as shown in FIG. 7 (FIG. 8G).

FIG. 9 illustrates a package structure of a semiconductor device disclosed in the patent document 2 (Japanese Patent Application Laid Open No. 2000-077595). FIG. 9A is a cross sectional view of the package structure and FIG. 9B is a top view of a lead frame included in the package structure. FIG. 9A is a cross sectional view taken on line Z-Z of FIG. 9B.

As shown in FIG. 9, the package structure of the semiconductor device disclosed in the patent document 2 includes a lead frame 201, a semiconductor chip 202, resin 203, a bonding wire 204, a interposer wiring (relay conductor) 205, tape 206 that functions as an insulator for fastening the wire 205 respectively, a first bonding stitch 207, and a second bonding stitch 208.

The tape 206 and the wiring 205 are combined to configure an interposer. The lead frame 201 is configured by a die pad 210 and an external frame 211. The interposer wiring 205 is configured by, for example, part of the lead frame base. The second bonding stitch 208 is disposed on the interposer and the first bonding stitch 207 is protruded partially outside the package.

According to the technique disclosed in the second patent document 2, if the array of the pads and the array of the outer lead pins cross each other on the subject semiconductor chip 202, then they come to be bonded through the interposer, thereby plural semiconductor devices having different signal wirings can be formed only with one type semiconductor chips 202.

### SUMMARY

According to the technique disclosed in the patent document 1, the package of the semiconductor device includes no interposer. Consequently, if a semiconductor chip (not shown) that is smaller in size than the die pad 104 is to be mounted/bonded, then the bonding stitch (not shown) design comes to be limited in flexibility, thereby the length of the (bonding) wire (not shown) is apt to be extended more than expected and it might cause electrical troubles in some cases.

On the other hand, according to the technique disclosed in the patent document 2, the insulation tape 206 used to fasten the wiring 205, which is a relaying conductor, is disposed at the back side surface of the lead frame 201, which is opposite to the bonding surface. This means that the insulation tape 206 is disposed at the back side surface of the die pad 210, thereby the die pad 210 cannot be exposed directly to the back side surface of the package. Thus the die pad 210 comes to be built in the package or the insulation tape 206 comes to be exposed from the package. This disturbs the heat release performance from the back side surface of the package. This is a problem.

A semiconductor device for an exemplary aspect includes a lead frame that includes a die pad of which back side surface is exposed to the back side of its package and plural land terminals; resin filled between the die pad and each of the land terminals so as to enable the die pad and each of those land terminals to be fastened mutually; a semiconductor chip that includes plural pads and is mounted at the top side of the die pad; an interposer that includes a bonding stitch at its top side and relays an electrical connection of at least any one of the pads to at least any one of the land terminals; and a first bonding wire bonded to the bonding stitch of the interposer and the object pad of the semiconductor chip.

In case of the exemplary aspect, because it includes an interposer that is high in design flexibility, even when the semiconductor chip is smaller in size than the die pad, a properly designed interposer leads to an optically designed bonding stitch. Consequently, the wire length (the first bonding wire length) can also be determined properly, thereby it can lower the probability of electrical trouble occurrence that cannot otherwise be avoided in case of the technique described in the patent document 1.

Furthermore, the interposer is disposed on the top side surface of the lead frame. The die pad and each of the land terminals are fastened mutually by resin filled therebetween. Consequently, the lead frame structure is stabilized and the die pad and each of the land terminals can be fastened mutually without sticking any tape, for example, on their back side surfaces. This is why the back side surface of the die pad can be exposed to the back side of the package, thereby the heat release performance of the package can be improved.

This means that the heat release performance of the package can be improved while the probability of electrical trouble occurrence is lowered.

Furthermore, a method of forming a semiconductor device of an exemplary aspect includes filling resin between a die pad and each of plural land terminals provided for a lead frame respectively. The back side surface of the die pad is exposed to the back side of the package of the subject semiconductor device and the resin functions to fasten the die pad and each of those land terminals mutually. The method also includes disposing an interposer on the top side surface of the lead frame. The interposer has a bonding stitch on its top side and relays an electrical connection of at least any one of the pads provided for the semiconductor chip to at least any one of the land terminals. The method further includes mounting the semiconductor chip on the top side of the die pad and a fourth step of bonding the bonding wire to the bonding stitch of the interposer and the pad of the semiconductor chip respectively.

According to the exemplary aspects, therefore, the heat release performance of the package can be improved while lowering the possibility of electrical defect occurrence.

### BRIEF DESCRIPTION OF THE DRAWINGS

The above and other exemplary aspects, advantages and features of the present invention will be more apparent from the following description of certain exemplary embodiments taken in conjunction with the accompanying drawings, in which:

FIGS. 1A and 1B illustrate a package structure of a semiconductor device in a first exemplary embodiment;

FIGS. 2A and 2B illustrate partial top views of the package structure of the semiconductor device in the first exemplary embodiment;

FIGS. 3A to 3K illustrate a series of processes for describing how to manufacture the semiconductor device in the first exemplary embodiment;

FIGS. 4A and 4B illustrate a package structure of a semiconductor device in a second exemplary embodiment;

FIGS. 5A and 5B illustrate a package structure of a semiconductor device in a third exemplary embodiment;

FIGS. 6A and 6B illustrate top views of a package structure of a semiconductor device in a fourth exemplary embodiment;

FIGS. 7A to 7C illustrate a package structure of a semiconductor device disclosed in the patent document 1;

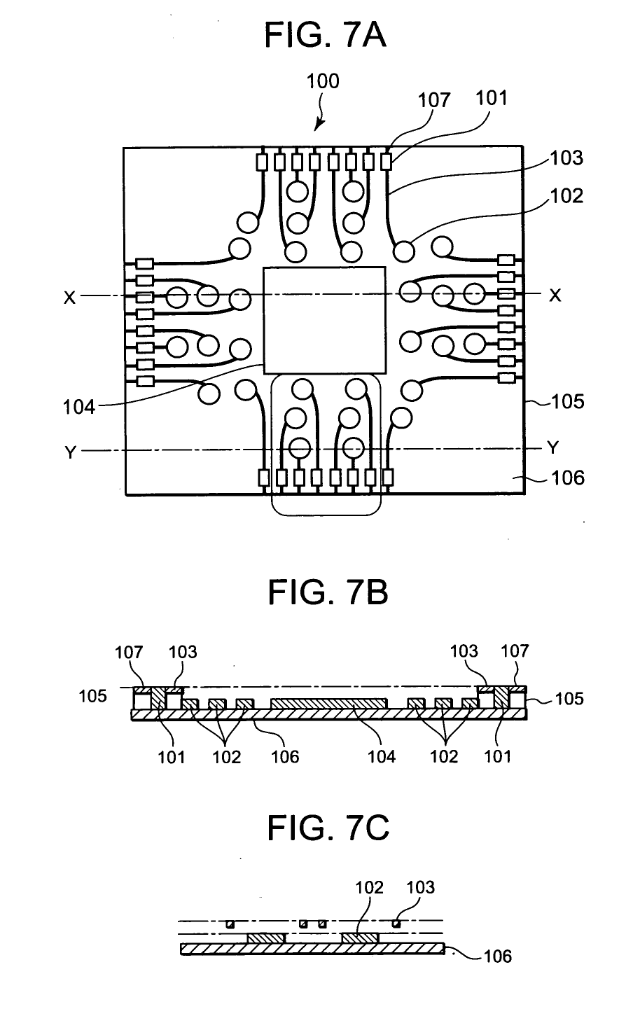

FIGS. 8A to 8G illustrate a series of processes for describing how to manufacture the semiconductor device disclosed in the patent document 1; and

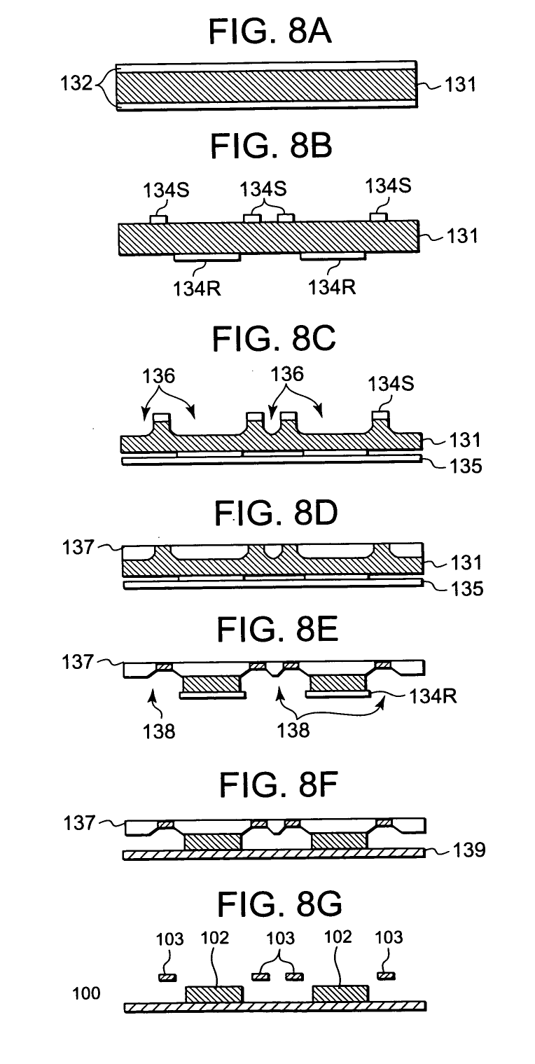

FIGS. 9A and 9B illustrate a package structure of a semiconductor device disclosed in the patent document 2.

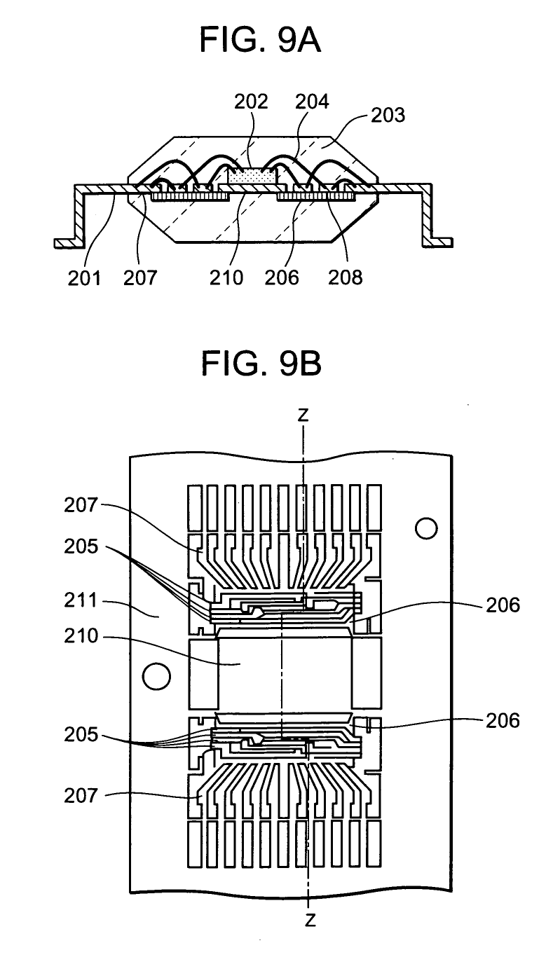

### DETAILED DESCRIPTION OF THE EXEMPLARY EMBODIMENTS

### First Exemplary embodiment

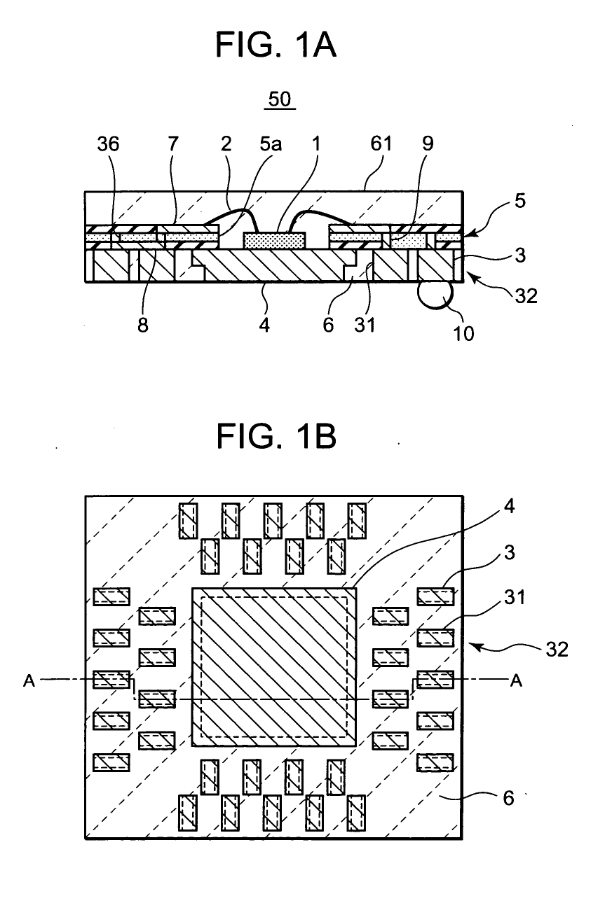

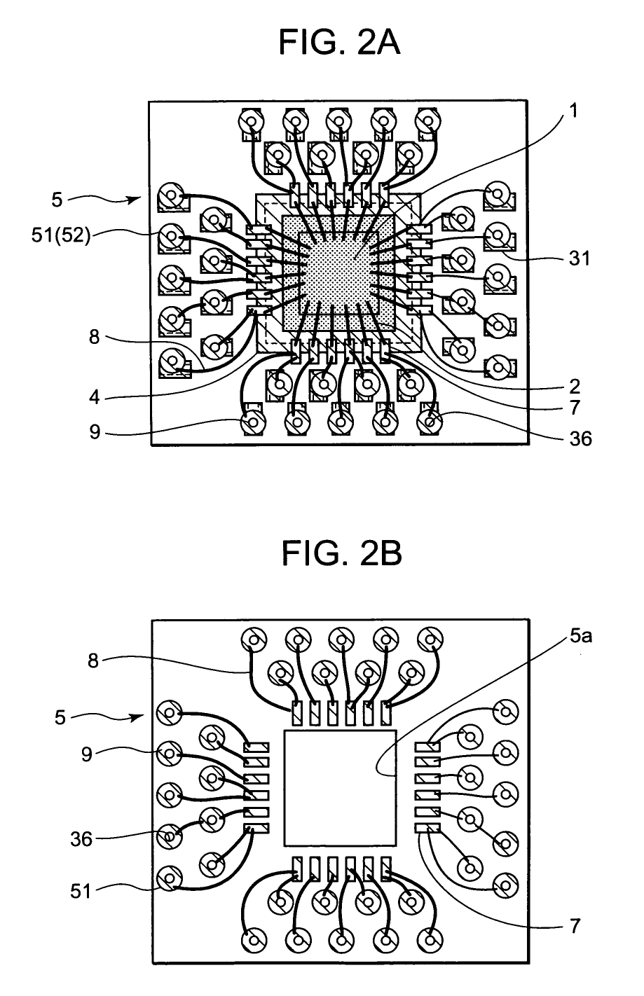

FIG. 1 illustrates a package structure of a semiconductor device 50 in a first exemplary embodiment. FIG. 1A is a cross sectional view of the package structure and FIG. 1B is a top view of a frame part 32 included in the package structure of the semiconductor device 50. FIG. 1A is a cross sectional view taken on line A-A of FIG. 1B. FIG. 2 illustrates partial views of the package structure of the semiconductor device 50 in the first exemplary embodiment. FIG. 2A is a top view of the package structure from which resin 61 is omitted. FIG. 2B is a top view of an interposer 5.

The semiconductor device 50 includes a lead frame 3 that includes a die pad 4 of which back side surface is exposed to the back side of the package; resin 6 filled between the die pad 4 and each of plural land terminals 31 so as to enable the die pad 4 and each of those land terminals 31 to be fastened mutually; a semiconductor chip having plural pads and being mounted at the top side of the die pad 4; an interposer 5 having a bonding chip 7 at its top side and disposed at the top side surface of the lead frame 3 so as to connect at least any one of the pads of the semiconductor chip 1 electrically to at least any one of the land terminals; and a bonding wire (first bonding wire) 2 bonded to a bonding stitch 7 of the interposer 5 and the object pad of the semiconductor chip 1, respectively. The semiconductor manufacturing method includes filling resin 6 between the die pad 4 of which back side surface is exposed to the back side of the package and each of the land terminals 31 of the lead frame 3 so as to enable the die pad 4 and each of the land terminals 31 to be fastened mutually; disposing the interposer 5 at the top side surface of the lead frame 3, the interposer 5 having a bonding stitch 7 at its top side and being used to connect at least any one of the pads of the semiconductor chip 1 electrically to at least any one of the land terminals 31; mounting the semiconductor chip 1 at the top side of the die pad 4; and bonding the bonding wire 2 to the bonding stitch 7 of the interposer 5 and the object pad of the semiconductor chip 1, respectively.

As shown in FIG. 1, the semiconductor device 50 includes, for example, a semiconductor chip 1, a bonding wire 2, a lead frame 3, an interposer 5, resin 6 and 61, and a ball 10.

The lead frame 3 includes a die pad 4 and plural land terminals 31. The lead frame 3 is made of a conductive material (e.g., metal) entirely. The resin 6 is filled between the die pad 4 and each of the land terminals 31. The resin 6 functions to fasten the die pad 4 and each of the land terminals 31 mutually.

The resin 6, the die pad 4, and the land terminals 31 (top of FIG. 1A) are all aligned, for example, at their top side surfaces respectively. The resin 6, the die pad 4, and the land terminals 31 are also aligned, for example, at their back side surfaces (bottom in FIG. 1A) respectively.

Hereunder, the part including the resin 6, the die pad 4, and the land terminals 31 will be referred to as a lead frame block 32.

On the top side surface of the die pad 4 is directly mounted the semiconductor chip 1 having plural pads (not shown).

On the top side surfaces of the resin 6, the die pad 4, and the land terminals 31, that is, on the top side surface of the lead frame block 32 is disposed the interposer 5.

The interposer 5 functions as a relay conductor that connects at least any one of the pads of the semiconductor chip 1 to at least any one of the land terminals 31 of the lead frame 3. As shown in FIG. 1A and FIG. 2B, the interposer 5 includes a bonding stitch 7, a wiring 8, and a via 9 that is buried in a via hole 36 formed in the interposer 5. The bonding stitch 7 is disposed at the top side surface of the interposer 5 and the wiring 8 is disposed at the back side surface thereof. The wiring 8 is connected to the bonding stitch 7 electrically through the via hole 9.

The interposer 5 formed as described above can be configured of a printed board having a desired wiring pattern formed on each of the front and back side surfaces thereof. This means that the wiring formed at the top side surface of the printed board can be used as the bonding stitch 7 and the wiring formed at the back side surface can be used as the wiring 8. The interposer 5 can be replaced with tape having a desired wiring pattern (e.g., made of Cu) on each of the front and back side surfaces thereof. In the first exemplary embodiment, the interposer 5 is configured of a printed board.

For example, part of the bonding stitch 7 of the interposer 5 is connected to the wiring 8 through the via 9 and the rest of the bonding stitch 7 is connected to the object land terminal 31 through the via 9. More concretely, the interposer 5 includes land terminals 51 and 52 at the front and back sides of the via 9 respectively. Thus the bonding stitch 7 is, for example, connected to the via 9 through a land terminal 51 and the via 9 is connected to the wiring 8 or the object land terminal 31 of the lead frame 3 through the land terminal 52. Furthermore, the wiring 8 is connected to the object land terminal 31.

In the center of the interposer 5 is formed an opening 5a through which the semiconductor chip 1 is to be disposed inside the interposer 5. The size of the opening 5a is decided properly in accordance with the size of the semiconductor chip 1. The bonding stitch 7 of the interposer 5 is disposed in accordance with the array of the pads of the semiconductor chip 1.

As shown in FIGS. 1A and 2A, the bonding wire 2 is bonded to the bonding stitch 7 of the interposer 5 and the object pad (not shown) of the semiconductor chip 1 respectively, thereby the bonding stitch 7 and the semiconductor chip 1 are connected electrically to each other.

The resin 61 covers the top side surfaces of all of the semiconductor chip 1, the die pad 4, the interposer 5, and the bonding stitch 7. The bonding wire 2 is buried in the resin 61.

The back side surface of the die pad 4 is exposed to the back side of the package of the semiconductor device 50. This means that the back side of the die pad 4 is not covered by the resin 6 and not covered by anything else, such as tape or the like. This is why the die pad 4 can be exposed to the back side of the lead frame block 32. Here, the back side of the lead frame block 32 means the opposite side of the semiconductor chip 1 mounted side in the lead frame 3 (die pad 4).

In this exemplary embodiment, because the back side surface of the die pad 4 is exposed to the back side of the package in such a way, the heat releasing performance of the package is improved.

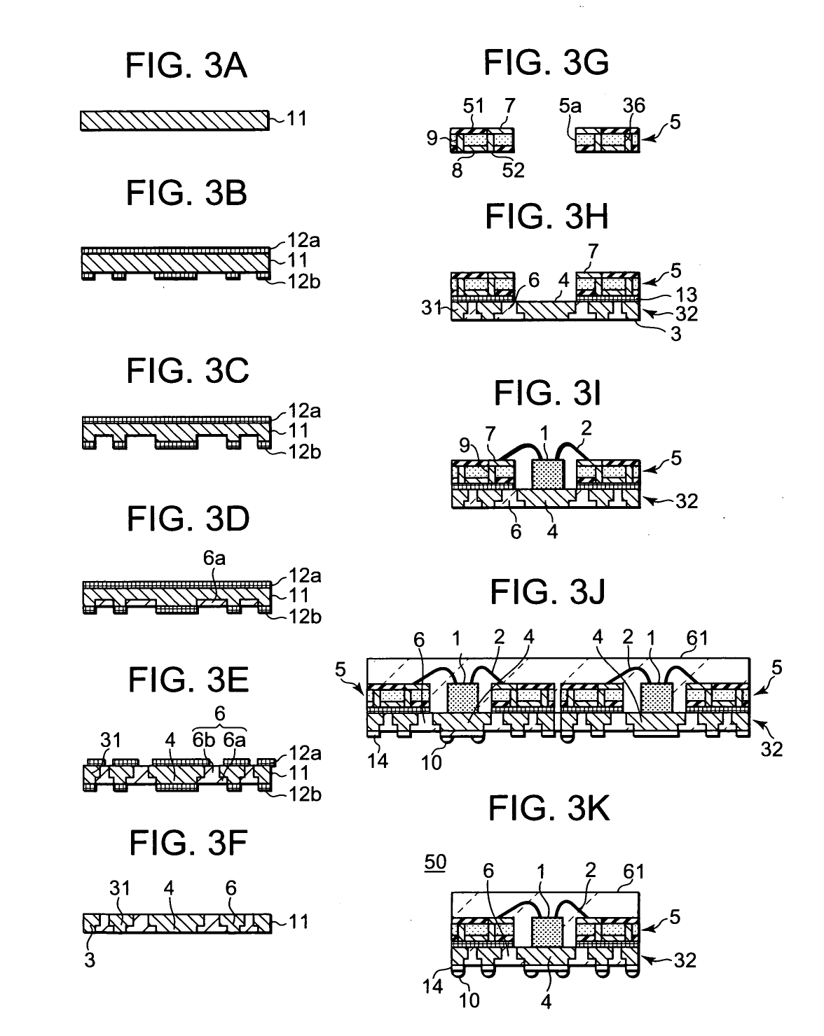

As to be described later, external plating 14 may be applied to the back side surface of the die pad 4 or a solder ball 10 may be provided on the surface (FIG. 3K). However, because metal is used for the external plating 14 and for forming the ball 10, the thermal conductivity becomes higher than that of the resin (and that of the tape). Therefore, even when the die pad 4 is covered by the external plating 14 and the ball 10, the heat releasing performance comes to be almost the same as that in the case where the back surface of the die pad 4 is exposed directly to the back side surface of the semiconductor device 50.

FIG. 3 illustrates a series of processes for describing the semiconductor device manufacturing method employed in the first exemplary embodiment.

At first, a lead frame base 11 is prepared (FIG. 3A). Then, photo-resist films 12a and 12b are formed on the top and back surfaces of this lead frame base 11 respectively. The photo-resist film 12b formed on the back side is patterned as predetermined. In the lead frame base 11, the pattern 12b covers the part, to be assumed as the die pad 4, as well as the back side surface of the part to be assumed as the land terminals 31 with the photo-resist film 12b (FIG. 3B).

After that, half-etching (first half-etching) is applied to the lead frame base 11, beginning at the back surface (one side surface) (FIG. 3C). Then, resin (first resin) 6a (part of the resin 6) is filled in each recessed part formed at the back side surface through this half-etching. For example, the back side surface of the lead frame base 11 is aligned to the back side surface of the resin 6a (FIG. 3D).

After that, the top side photo-resist film 12a is patterned as predetermined. After this patterning, the photo-resist film 12a comes to cover only the top side surfaces of the part to be assumed as the die pad 4 of the lead frame base 11 and the part to be assumed as the object land terminal 31. Then, half-etching (second half-etching) is carried out for the lead frame base 11, beginning at the top side surface (the other side surface) to separate the die pad 4 and each of the land terminals 31 from each other. Then, the resin 6b is filled between the die pad 4 and each of the land terminals 31. The resin 6b is the rest part of the resin 6 including resin 6a and resin 6b. At the part between the die pad 4 and each of the land terminals 31, the resin 6b at the top side and the resin 6a at the back side are connected to each other. In this stage, the die pad 4 and each of the land terminals 31 come to be electrically insulated from each other (FIG. 3E).

After that, the photo-resist films 12a and 12b are removed. With this removal, the lead frame block 32 is obtained (FIG. 3F).

After that, the interposer 5 that is already formed (FIG. 3G) is disposed on the top side surface of the lead frame block 32 (FIG. 3H). At this time, for example, an unisotropic conductive bonding agent 13 is used to stick the interposer 5 to the lead frame block 32, thereby the lead frame block 32 and the interposer 5 are connected electrically to each other.

Then, the semiconductor chip 1 is mounted on the die pad 4 and the semiconductor chip 1 and the bonding stitch 7 are connected electrically to each other through the bonding wire 2 (FIG. 31).

Next, the above components are packaged by the resin 61. In other words, the top side surfaces of the semiconductor chip 1, the die pad 4, the resin 6, and the interposer 5 are covered by the resin 61 and the bonding wire 2 is buried in this resin 61. Furthermore, for example, plural packages are packaged collectively by the resin 61. Furthermore, external plating 14 (electrolessly plating in this exemplary embodiment) is carried out for the back side surfaces of the die pad 4 and the land terminals 31. Furthermore, the ball 10 is provided for the back side surfaces of the die pad 4 and the land terminals 31 through the external plating 14 (FIG. 3J).

Next, the boundaries among those packages are cut off to separate those packages to respective ones (FIG. 3K). With this, the semiconductor devices 50 are obtained.

Here, plural packages are packaged with the resin 61 simultaneously. However, those packages may also be packaged one by one with the resin 61 (single packaging).

In FIG. 3K, a BGA (Ball Grid Array) type semiconductor device 50 is picked up as an example. The semiconductor device 50 may also be manufactured as any of the QFN (Quad Flat Non-Lead Package) type one as shown in FIG. 1A or the LGA (Land Grid Array) type one.

As described above, the semiconductor device 50 in the first exemplary embodiment includes a lead frame 3 that includes a die pad 4 exposed to the back side of its package and plural land terminals 31; resin 6 filled between the die pad 4 and each of the land terminals 31 so as to fasten the die pad 4 and each of those land terminals 31 mutually; a semiconductor chip 1 that includes plural pads and is mounted at the top side of the die pad 4; an interposer 5 that includes a bonding stitch 7 at its back side and relays an electrical connection of at least any one of the pads to at least any one of the land terminals 31; and a bonding wire 2 bonded to the bonding stitch 7 and the object pad of the semiconductor chip 1 respectively. In other words, because of the interposer 5 to be designed flexibly as described above, even when the semiconductor chip 1 is smaller in size than the die pad 4, the bonding stitch 7 can be designed properly in case where the interposer 5 is designed properly. Consequently, the wire length (the length of the bonding wire 2) can also be determined properly and this can lower the probability of electrical trouble occurrence that cannot otherwise be avoided in case of the technique disclosed in the patent document 1.

More concretely, the interposer 5 includes a wiring 8 at its back side and a bonding stitch 7 at its top side and the bonding stitch 7 is connected electrically to the wiring 8 through a via 9. Thus the flexibility of the bonding wire 2 in design can be improved. Even when the array of the pads of the semiconductor chip 1 and the array of the external terminals cross each other, the wiring and connecting can be made as desired. Furthermore, in case where the interposer 5 is designed properly, the bonding stitch 7 can be designed so as to optimize the length and the laying route of the bonding wire 2 regardless of the sizes of the die pad 4 and the semiconductor chip 1 mounted on the die pad 4.

Furthermore, the interposer 5 is disposed at the top side surface of the lead frame 3 and the die pad 4 and each of the land terminals 31 are fastened mutually by the resin 6 filled therebetween. Consequently, the structure of the lead frame block 32 is stabilized, thereby, for example no tape or the like is needed to stick the back side surfaces of the die pad 4 and each of the land terminals 31 so as to fasten them mutually. This is why the back side surface of the die pad 4 can be exposed to the back side of the package, thereby the heat releasing performance of the package is improved. This is why other semiconductors 1 used for the power system (high current and high heat generation ones) come to be employed for the semiconductor device 50.

### Second Exemplary Embodiment

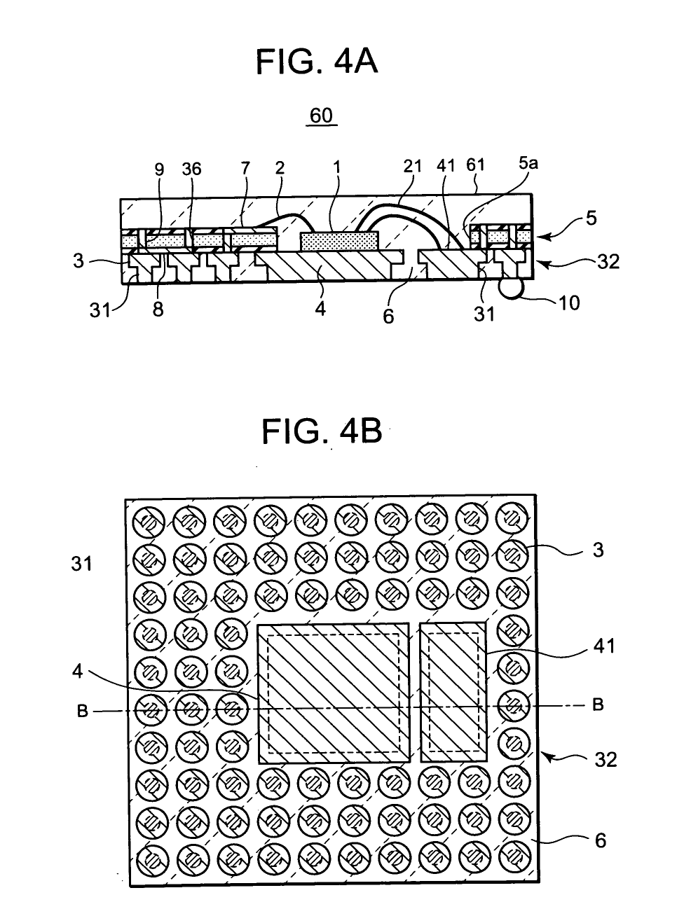

FIG. 4 illustrates a package structure of a semiconductor device 60 employed in a second exemplary embodiment. FIG. 4A is a cross sectional view of the package structure and FIG. 4B is a top view of a lead frame block 32 included in the package structure. The cross sectional view shown in FIG. 4A is taken on line B-B of FIG. 4B.

In the first exemplary embodiment described above, the bonding stitch 7 is disposed on the interposer 5 entirely. However, the printed board or tape used as the interposer 5 is soft (low rigidity). Consequently, when ultrasonic bonding is applied so as to bond a thick bonding wire 21 (A1 or so) (FIG. 4A) to the interposer 5, the bonding stitch 7 might sink due to the influences of the ultrasonic wave and its load. This has made such a bonding work difficult. According to the technique disclosed in the patent document 1, the tape 139 is stuck on the back side surface of the lead frame 100 to prevent the lead frame 100 from deformation. As a result, the bonding stitch part comes to float. This makes it difficult to hold the bonding stitch part surely and makes it further difficult to carry out the ultrasonic bonding that uses a thick wire such as an A1 one.

In the second exemplary embodiment, therefore, the bonding wire (second bonding wire) 21 (FIG. 4A) is bonded onto the lead frame 3. This has made it easier to carry out the bonding even when such a thick wire as an A1 one is used as the bonding wire 21. The bonding wire 21 is thicker than the bonding wire 2.

As shown in FIG. 4, in the second exemplary embodiment, the size of at least one of the land terminals 31 is determined so as to enable the thick bonding wire 21 to be bonded onto the top side surface of the land terminal 31. Furthermore, the size and shape of the opening 5a of the interposer 5 are determined so that part of the surface of the land terminal (the selected one) is not covered by the interposer 5. On the surface of the selected one land terminal 31, the thick bonding wire 21 is bonded directly to part of the surface that is not covered by the interposer 5. The other end of the bonding wire 21 is bonded to one of the pads provided for the semiconductor chip 1, which is different from the pad to which the bonding wire 2 is bonded. Consequently, the selected land terminal 31 and the semiconductor chip 1 are connected electrically to each other.

Furthermore, for example, a bonding stitch 41 should preferably be provided on part of the top side surface of the land terminal 31 (FIG. 4B) and the bonding wire 21 should be bonded to the bonding stitch 41. This is because the bonding stitch 41 provided in such a way makes such bonding more easily and more surely. However, it is also possible here to bond the bonding wire 21 directly to the object land terminal 31 without forming the bonding stitch 41.

According to the second exemplary embodiment, therefore, in addition to the effect obtained by the first exemplary embodiment described above, the following effect can also be obtained.

If the interposer 5 and the lead frame 3 are designed properly, then at least one of the bonding wires 2 and 21 (bonding wire 21) can be bonded to the object land terminal 31 of the lead frame 3.

Particularly, if the bonding wire 21 that is thicker than the bonding wire 2 is bonded to the object land terminal 31 of the lead frame 3, then the bonding can be made more favorably. This is because the land terminal 31 is fastened by the resin 6. As a result, the land terminal 31 does not sink easily even when it is affected by the ultrasonic wave and its load. Furthermore, a larger current can be flown through the thick bonding wire 21 (when compared with that in case where the thinner bonding wire 2 is used). This means that the heat releasing performance of the package of the semiconductor device 60 is improved and the package comes to be able to cope with larger current flows.

Furthermore, because a bonding stitch 41 is provided on the top surface of at least any one of the land terminals 31 and the bonding wire 21 is bonded to the bonding stitch 41, the bonding can be made more easily and surely.

### Third Exemplary Embodiment

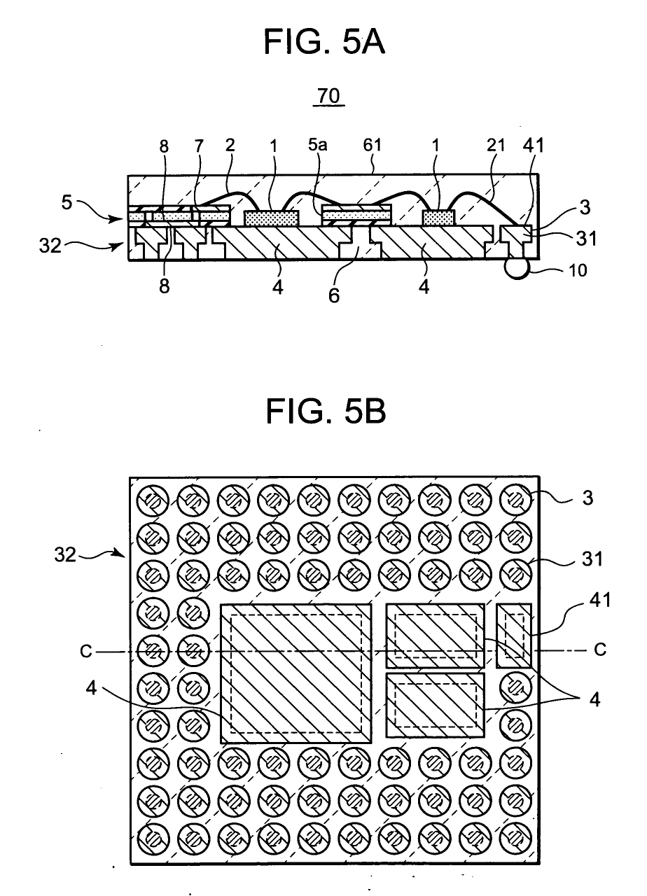

FIG. 5 illustrates a package structure of a semiconductor device 70 in a third exemplary embodiment. FIG. 5A is a cross sectional view of the package structure of the semiconductor device 70 and FIG. 5B is a top view of a lead frame block 32 included in the package structure of the semiconductor device 70. The cross sectional view shown in FIG. 5 is taken on line C-C of FIG. 5B.

In this exemplary embodiment, the semiconductor device 70 includes plural die pads 4 and semiconductor chips 1 are mounted on those die pads 4 respectively. Other items of the semiconductor device 70 are the same as those of the semiconductor device 60 in the second exemplary embodiment described above. Each of the die pads 4 is formed in accordance with the size of the semiconductor chip 1 mounted thereon.

According to the third exemplary embodiment described above, therefore, electrical troubles that might otherwise occur in the (multi-chip) semiconductor device 70 having plural semiconductor chips 1 can be prevented and the heat releasing performance of the package of the semiconductor device 70 can be improved.

### Fourth Exemplary Embodiment

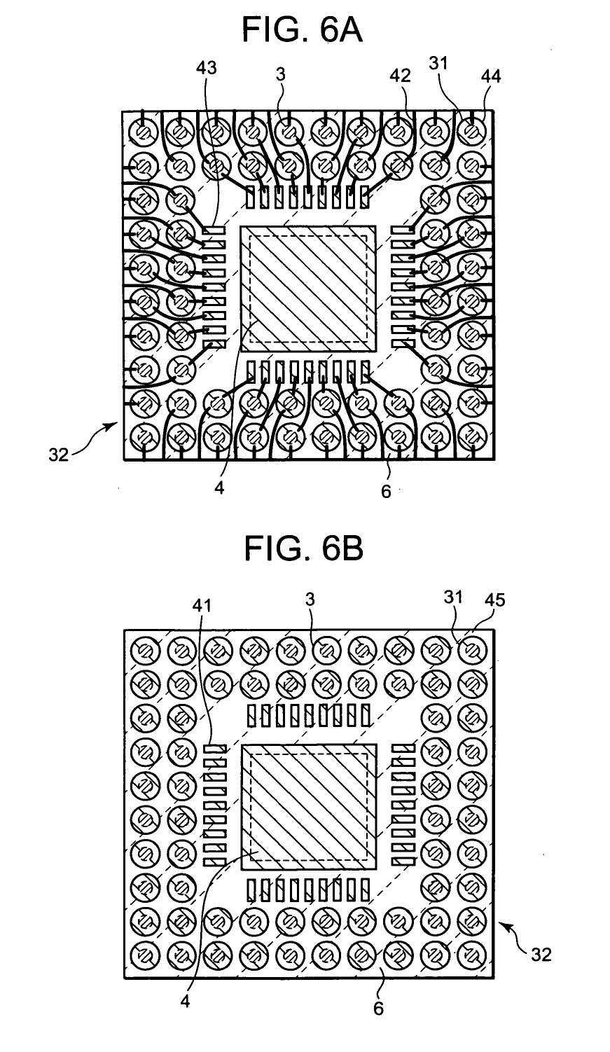

FIG. 6 illustrates a package structure of a semiconductor device in a fourth exemplary embodiment. FIG. 6A is a top view of a lead frame block 32 of the semiconductor device in the fourth exemplary embodiment. FIG. 6B is a top view of the lead frame block 32 of the semiconductor device 60 in the second exemplary embodiment in comparison with that in FIG. 6A.

In the exemplary embodiment, as shown in FIG. 6A, one or at least one of plural land terminals 31 has a bonding stitch 43 on its top side surface. The lead frame 3 includes a lead wiring (metal) 42 used for electrolytic plating. The wiring is led to the outer periphery of the semiconductor device package from the bonding stitch 43 provided for the object land terminal 31.

The half-etching is carried out for the front layer side of the lead frame 3 as shown in FIG. 3E so that this lead wiring used for electrolytic plating 42 is left over, thereby the lead wiring used for electrolytic plating 42 is formed at the front layer side of the lead frame 3.

In the exemplary embodiment, the resin 6 is filled between the lead frames 3 of the lead frame block 32. Consequently, the lead wiring used for the electrolytic plating 42 can be formed by thin wire (e.g., at a line width of 50 μm or so and at an interval of 50 μm or so between lines). Even in this case, the lead wiring used for the electrolytic plating 42 can be formed so as not to be bent easily while the lead frame block 32 is carried.

In the exemplary embodiment, the lead frame 3 has such a lead wiring used for the electrolytic plating 42, so that the electrolytic plating can be made, for example, on the bonding stitch 43 and on the back side surface of the object land terminal 31 to be assumed as an external terminal 44 (FIG. 6A). In other words, such electrolytic (not electroless plating) plating can be carried out instead of the Ag plating to be carried out on the bonding stitch or on the die pad in a general lead frame manufacturing process, as well as instead of the external plating to be carried out with solder, zinc, etc. in a general mold package manufacturing process. In case of the electroless plating, it is difficult to form a thick plating film. On the other hand, the electrolytic plating can make the film thicker than that in case of the electroless plating. This is why the bonding wire 21 can be bonded or the ball 10 can be fastened with solder more easily and surely, thereby the structure of the package can be further stabilized.

As shown in FIG. 6B in comparison with the example in the exemplary embodiment, if the lead frame 3 has no lead wiring used for the electrolytic plating 42, then only electroless plating is possible on the bonding stitch 41 and on the back side surface of the object land terminal 31 to be assumed as an external terminal 45. This makes it difficult to form a thick plating film.

As described above, according to the fourth exemplary embodiment as described above, a bonding stitch 43 is provided on the top side surface of one or at least one of plural land terminals 31 and the lead frame 3 has a lead wiring used for electrolytic plating 42, which is laid from the bonding stitch 43 provided at the object land terminal 31 to the outer periphery of the package of the semiconductor device. For example, therefore, electrolytic plating can be carried out on the bonding stitch 43 and on the back side surface of the object land terminal 31 to be assumed as an external terminal 44 respectively.

In each of the exemplary embodiments described above, two wiring layers are provided for the interposer 5 (top side bonding stitch 7 and back side wiring 8). However, three wiring layers or more may also be provided for the interposer 5. In proportion to the number of the wiring layers of the interposer 5, those wirings can be laid in more complex patterns in the interposer 5. This is why even when the pads of the semiconductor chip 1 and the array of the external terminals cross each other in a more complex pattern, those wirings can be connected more easily as desired.

Further, it is noted that Applicant's intent is to encompass equivalents of all claim elements, even if amended later during prosecution.

What is claimed is:

1. A semiconductor device, comprising:
a lead frame including a die pad of which a back side surface is exposed to a back side of a package, and a plurality of land terminals;
a resin filled between the die pad and each of the land terminals so as to enable the die pad and each of the land terminals to be fastened mutually;
a semiconductor chip having a plurality of pads and being mounted on a top side of the die pad;
an interposer having a bonding stitch on its top side, being disposed on a top side surface of the lead frame, and relaying an electrical connection of at least any one of the plurality of pads to at least any one of the land terminals; and
a first bonding wire bonded to the bonding stitch of the interposer and one of the plurality of pads of the semiconductor chip.

2. The semiconductor device according to claim 1, further comprising:
a plurality of die pads including the die pad,
wherein the semiconductor chip is mounted on each of the plurality of die pads.

3. The semiconductor device according to claim 1, further comprising:
a second bonding wire bonded to another pad of the plurality of pads, and to the lead frame.

4. The semiconductor device according to claim 3,
wherein the second bonding wire is thicker in diameter than the first bonding wire.

5. The semiconductor device according to claim 3,
wherein the bonding stitch is provided on at least any one of the land terminals and is bonded to the second bonding wire.

6. The semiconductor device according to claim 5,
wherein the lead frame includes a metal wiring led to an outer periphery of the package of the semiconductor device from the bonding stitch provided for the land terminal.

7. The semiconductor device according to claim 1, wherein the interposer comprises:
a wiring positioned at a back side of the interposer and connected electrically to the land terminal; and
a via that enables the wiring to be connected electrically to the bonding stitch.

8. A method of forming a semiconductor device, comprising:
filling a resin between a die pad of which a back side surface is exposed to a back side of a package and a plurality of land terminals provided for a lead frame so that the resin can fasten the die pad and each of the land terminals mutually;
disposing an interposer at a top side surface of the lead frame, the interposer having a bonding stitch at its top side and being used to relay an electrical connection of at least any one of a plurality of pads of a semiconductor chip to at least any one of the plurality of land terminals;
mounting the semiconductor chip on a top side of the die pad; and
bonding a bonding wire to the bonding stitch of the interposer and the pad of the semiconductor chip.

9. The method according to claim 8, wherein the filling the resin comprises:
carrying out a first half-etching for a lead frame base, beginning at its one side surface;
filling a first resin that is part of the resin in a recessed part formed at the lead frame base through the first half-etching;
carrying out a second half-etching for the lead frame base, beginning at its other side surface; and
filling a second resin that comprises a reminder of the resin in the recessed part formed at the lead frame base through the second half-etching.

10. A semiconductor device, comprising:
a die pad including a first surface and a second surface;
a land terminal including a first surface and a second surface;
a semiconductor chip formed on the first surface of the die pad;
an interposer including a bonding stitch and a via electrically connected between the bonding stitch and the first surface of the land terminal;
a bonding wire connected between the semiconductor chip and the bonding stitch; and
a resin provided between the die pad and the land terminal, and provided to cover the semiconductor chip, the bonding wire and the interposer, the resin being absent on the second surfaces of the die pad and land terminal.

11. The semiconductor device of claim 10, further comprising:
a solder ball provided on the second surface of the die pad.

12. The semiconductor device of claim 10, wherein the interposer is comprised by a tape including a wiring pattern.

13. The semiconductor device of claim 10, wherein the interposer is comprised by a printed board.

14. The semiconductor device of claim 10, further comprising:
a second bonding wire connected between the semiconductor chip and the land terminal without intervening the interposer.
